(19) United States
(12) Patent Application Publication
(10) Pub. No.: US 2015/0075960 A1
(43) Pub. Date: Mar. 19, 2015

(54) TOUCH PANEL

(71) Applicants: Chi-Ming Hsieh, Taichung City (TW); Shyh-Jeng Chen, Taichung City (TW); Chia-Lun Chang, Taoyuan County (TW); Chun-Ming Huang, Taichung City (TW); Kuo-Hsing Chen, New Taipei City (TW); Chen-Hao Su, Taichung City (TW)

(72) Inventors: Chi-Ming Hsieh, Taichung City (TW); Shyh-Jeng Chen, Taichung City (TW); Chia-Lun Chang, Taoyuan County (TW); Chun-Ming Huang, Taichung City (TW); Kuo-Hsing Chen, New Taipei City (TW); Chen-Hao Su, Taichung City (TW)

(73) Assignee: WINTEK CORPORATION, Taichung City (TW)

(21) Appl. No.: 14/484,292

(22) Filed: Sep. 12, 2014

(30) Foreign Application Priority Data
Sep. 14, 2013 (TW) 102133385

(51) Int. Cl. G06F 1/16; H03K 17/96; G06F 3/0354

(52) U.S. Cl. CPC G06F 1/1692; G06F 3/03547; H03K 17/962; H03K 2217/960755; H03K 2017/9613; H03K 2217/96077
USPC 200/600

(57) ABSTRACT

A touch panel including a substrate, at least one decoration layer, and a conductive electrode structure is provided. The decoration layer is disposed on at least one side of the substrate. The decoration layer has at least one hot key area. The hot key area includes a hot key pattern area and a hot key touching area. The hot key touching area is located on at least one side of the hot key pattern area without overlapping each other. The decoration layer has at least one recess disposed in the hot key pattern area. The conductive electrode structure is disposed on the decoration layer. The conductive electrode structure is located in the hot key touching area, and an orthogonal projection of the conductive electrode structure on the substrate and an orthogonal projection of the recess on the substrate do not overlap with each other.

### CROSS-REFERENCE TO RELATED APPLICATION

This application claims the priority benefit of Taiwan application serial no. 102133385, filed on Sep. 14, 2013. The entirety of the above-mentioned patent application is hereby incorporated by reference herein and made a part of this specification.

### BACKGROUND OF THE INVENTION

1. Field of the Invention

The invention is related to a touch panel, and more particularly to a touch panel having a hot key design.

2. Description of Related Art

In the era of information explosion, people view effectiveness as a valuable quality. Therefore, as for smart terminal products such as hand-held electronic devices including smart phones or tablet computers, not only having multiple functions and light and thin appearances, users also expect to execute required functions in a short time and switch between each application quickly when using the smart terminal products. Among the aforementioned functions, the functions (for example, editing text messages, querying calling records, or returning from/to the home page) that are frequently used by the users are even more important.

In order to fulfill the above requirements, taking smart phones or tablet computers for example, recent manufacturers of the smart terminal products commonly configure shortcut keys or hot keys in a decoration area of a smart phone or a tablet computer at the beginning of the product design. Generally, in the process of making the shortcut keys or the hot keys, it is required to carve part of a decoration layer located in the decoration area out to form an opening having a predetermined contour, such that this predetermined pattern contours of the shortcut keys or the hot keys are visible on the a touch panel. In addition, touch electrodes are disposed on the corresponding shortcut keys or hot keys, which allow the users to operate the smart phone or the tablet computer more intuitively.

However, since the decoration layer is formed on the surface of the substrate of the touch panel and has a certain thickness, there will be a height difference between the upper surface of the decoration layer near the aforementioned opening and the surface of the substrate of the touch panel. As a result, when manufacturing the touch electrodes corresponding to the shortcut keys or the hot keys, disconnection of the touch electrodes may occur due to the aforementioned height difference, which leads to a problem such as malfunction of the touching function corresponding to the shortcut key or the hot key or delay of the touching reaction.

### SUMMARY OF THE INVENTION

Accordingly, the invention provides a touch panel having an improved layout of a conductive electrode structure so as to prevent the problem such as malfunction of a touching function or delay of a touching reaction due to disconnection of the touch electrode structure.

The touch panel of the invention includes a substrate, at least one decoration layer, and a conductive electrode structure. The decoration layer is disposed on at least one side of the substrate and has at least one hot key area. The hot key area includes a hot key pattern area and a hot key touching area. The hot key touching area is located on at least one side of the hot key pattern area without overlapping each other. The decoration layer has at least one recess disposed in the hot key pattern area. The conductive electrode structure is disposed on the decoration layer. The conductive electrode structure is located in the hot key touching area, and an orthogonal projection of the conductive electrode structure on the substrate and an orthogonal projection of the recess on the substrate do not overlap with each other.

The touch panel of the invention includes a substrate, at least one decoration layer, and a conductive electrode structure. The decoration layer is disposed on at least one side of the substrate and has at least one hot key area. The hot key area includes a hot key pattern area and a hot key touching area. The hot key touching area is located on at least one side of the hot key pattern area without overlapping each other. The decoration layer has at least one recess disposed in the hot key pattern area. The conductive electrode structure is disposed on the decoration layer. The conductive electrode structure is located in the hot key touching area, wherein the conductive electrode structure is located out of the recess.

In an embodiment of the invention, the aforementioned decoration layer includes at least one ink layer, at least one photoresist layer, or a combination thereof.

In an embodiment of the invention, the aforementioned conductive electrode structure is formed by a one layer electrode.

In an embodiment of the invention, the aforementioned recess is a hot key pattern opening.

In an embodiment of the invention, the conductive electrode structure includes a first electrode and a second electrode, and the contour of the first electrode and the contour of the second electrode are at least partially complementary to each other.

In an embodiment of the invention, each of the first electrode and the second electrode includes a main electrode and a plurality of sub electrodes connecting to the main electrode, and the sub electrodes of the first electrode and the sub electrodes of the second electrode are arranged alternately.

In an embodiment of the invention, each of the sub electrodes of the first electrode extends toward the second electrode, and each of the sub electrodes of the second electrode extends toward the first electrode.

In an embodiment of the invention, the conductive electrode structure further includes a first extending electrode. The first extending electrode is connected to the first electrode and extends to the peripheral area of the hot key pattern area, and a part of the contour of the first extending electrode and the contour of the hot key pattern opening are complementary to each other.

In an embodiment of the invention, the conductive electrode structure further includes a second extending electrode. The second extending electrode is connected to the second electrode and extends to the peripheral area of the hot key pattern area, and a part of the contour of the second extending electrode and the contour of the hot key pattern opening are complementary to each other.

In an embodiment of the invention, the conductive electrode structure includes a first electrode, a second electrode, and a virtual electrode. The first electrode and the second electrode surround the hot key pattern area, and each of the first electrode and the second electrode includes a main electrode and a plurality of sub electrodes connected to the main electrode. The virtual electrode is located between the first electrode and the second electrode and located in the hot key pattern area.

In an embodiment of the invention, the virtual electrode includes a plurality of virtual sub electrodes, and a part of the virtual sub electrodes extend toward the first electrode while the other part of the virtual sub electrodes extend toward the second electrode. The plurality of virtual electrodes is located outside of the hot key pattern area.

In an embodiment of the invention, the part of the virtual sub electrodes are arranged alternately with the sub electrodes of the first electrode, while the other part of the virtual sub electrodes are arranged alternately with the sub electrodes of the second electrode.

In an embodiment of the invention, the contour of the part of the virtual sub electrodes and the contour of the hot key pattern opening are complementary to each other.

In an embodiment of the invention, the conductive electrode structure is connected to an external circuit.

In an embodiment of the invention, the recess includes a colored ink layer therein.

In an embodiment of the invention, the recess includes an ink layer having a low optical density.

In an embodiment of the invention, the ink layer having the low optical density has an optical density that is less than 2.5.

To sum up, in the touch panel of the invention, the hot key touching area is located on at least one side of the hot key pattern area without overlapping each other. The conductive electrode structure is disposed on the decoration layer and located in the hot key touching area. The contours of the first electrode and the second electrode of the conductive electrode structure are complementary to each other or selectively complementary to the contour of the recess. Therefore, the layout of the conductive electrode structure skirts the recess, so that the problem such as the malfunction of the touch function or the delay of the touching reaction due to the disconnection of the conductive electrode structure can be avoided.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a touch panel according to an embodiment of the invention.

FIG. 2A is a schematic view of partial layout of the conductive electrode structure located in an area A of FIG. 1.

FIG. 2B is a cross-sectional schematic view along a line I-I of FIG. 2A.

FIG. 2C is a cross-sectional schematic view of a conductive electrode structure according to another embodiment of the invention.

FIG. 2D is a partial layout schematic diagram of the conductive electrode structure according to another embodiment of the invention.

FIG. 3A to FIG. 3E are partial layout schematic diagrams of conductive electrode structures according to other embodiments of the invention.

FIG. 4 is a partial layout schematic diagram of a conductive electrode structure according to another embodiment of the invention.

FIG. 5 is a partial layout schematic diagram of a conductive electrode structure according to yet another embodiment of the invention.

FIG. 6A and FIG. 6B are partial layout schematic diagrams of a conductive electrode structure according to still another embodiment of the invention.

FIG. 7A is a partial layout schematic diagram of a conductive electrode structure according to further another embodiment of the invention.

FIG. 7B is a schematic cross-sectional view along a line J-J of FIG. 7A.

FIG. 8 and FIG. 9 are partial layout schematic diagrams of conductive electrode structures according to other possible embodiments of the invention.

### DESCRIPTION OF THE EMBODIMENTS

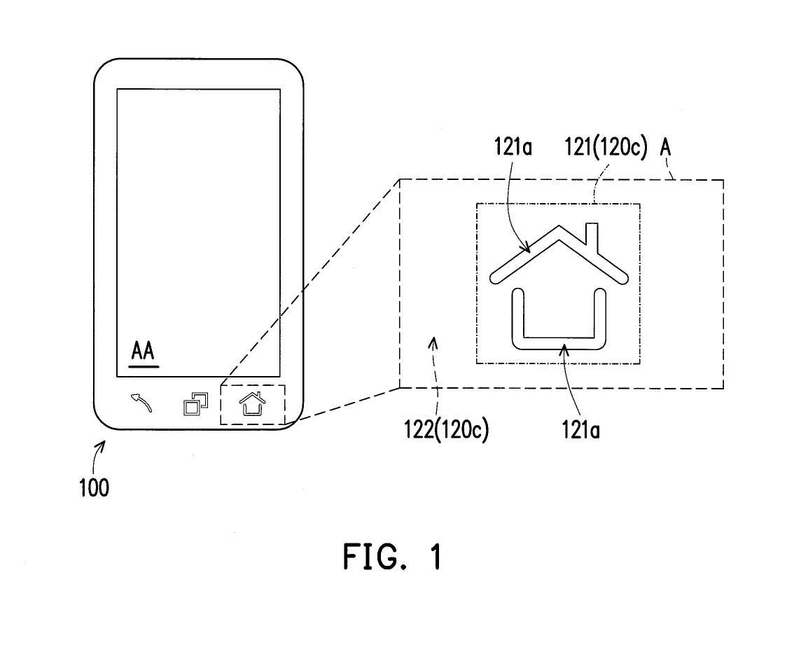

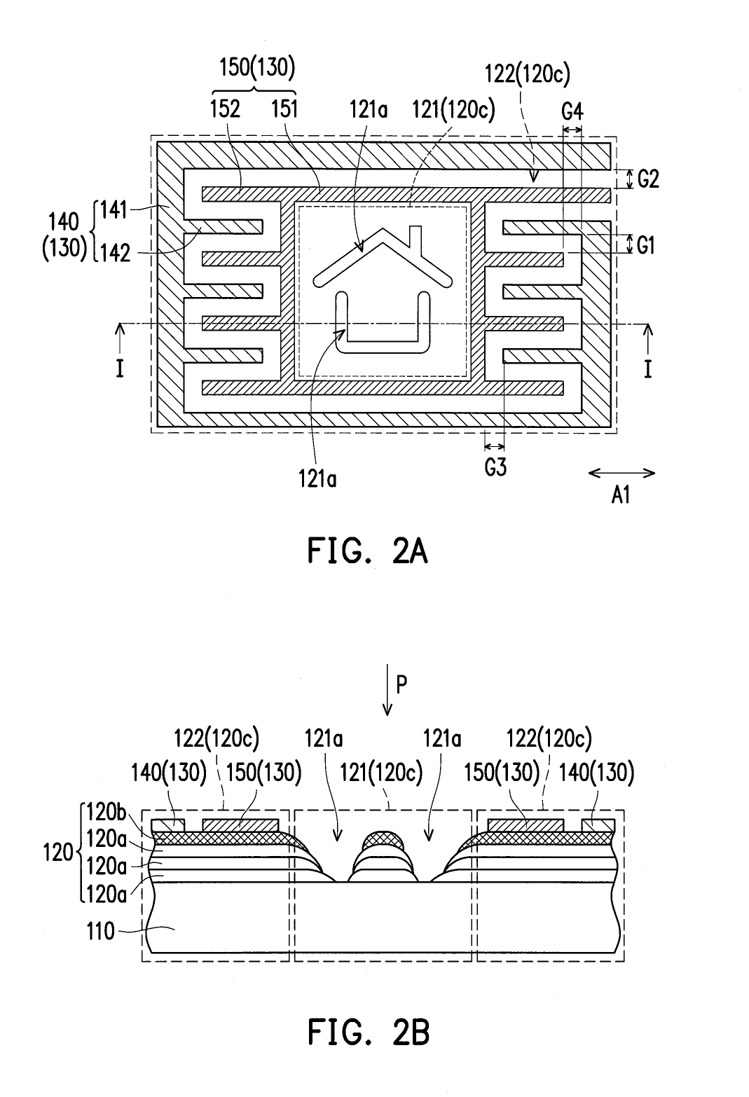

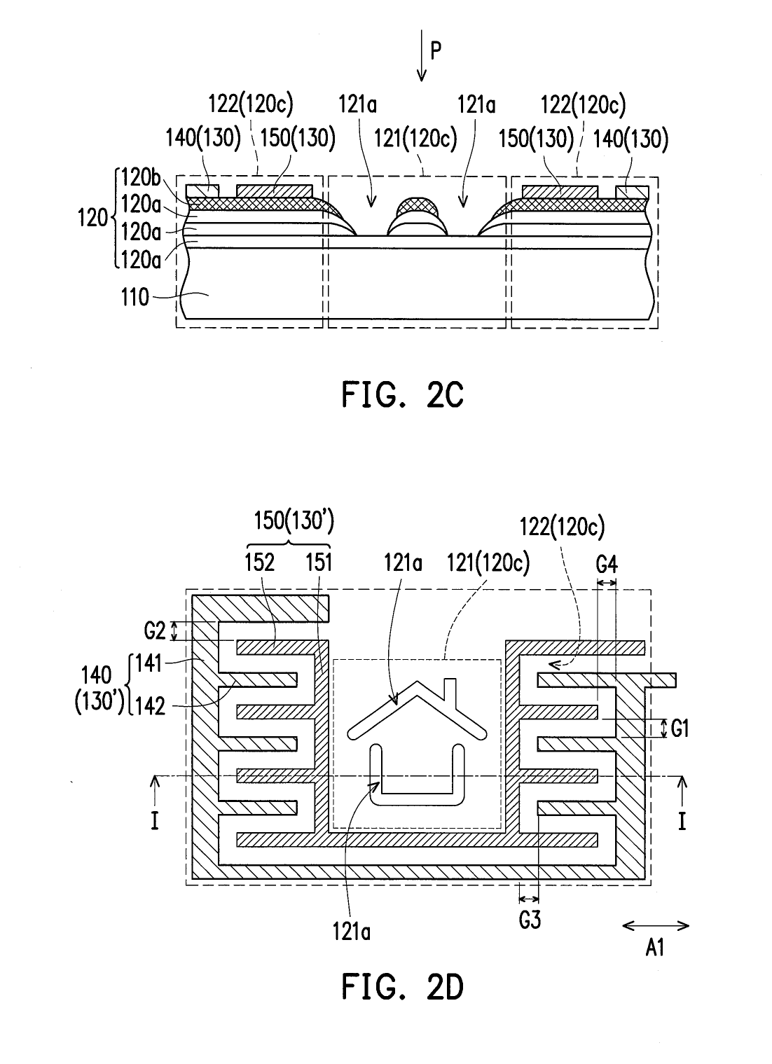

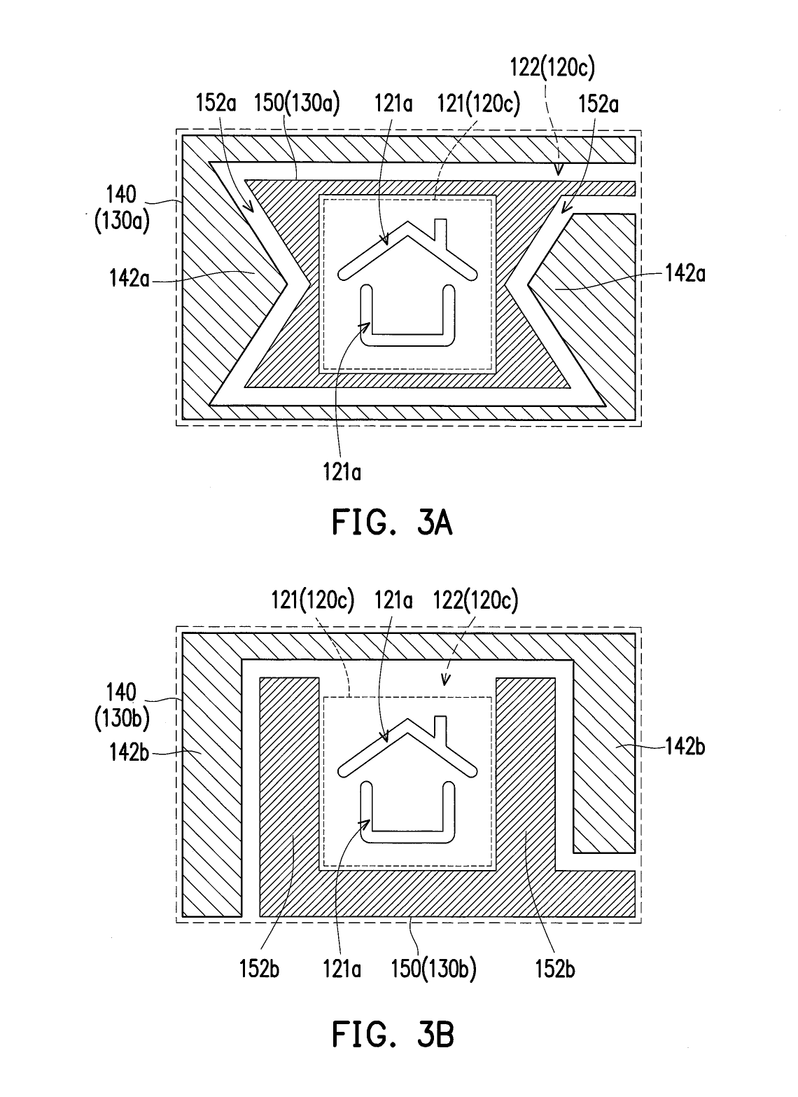

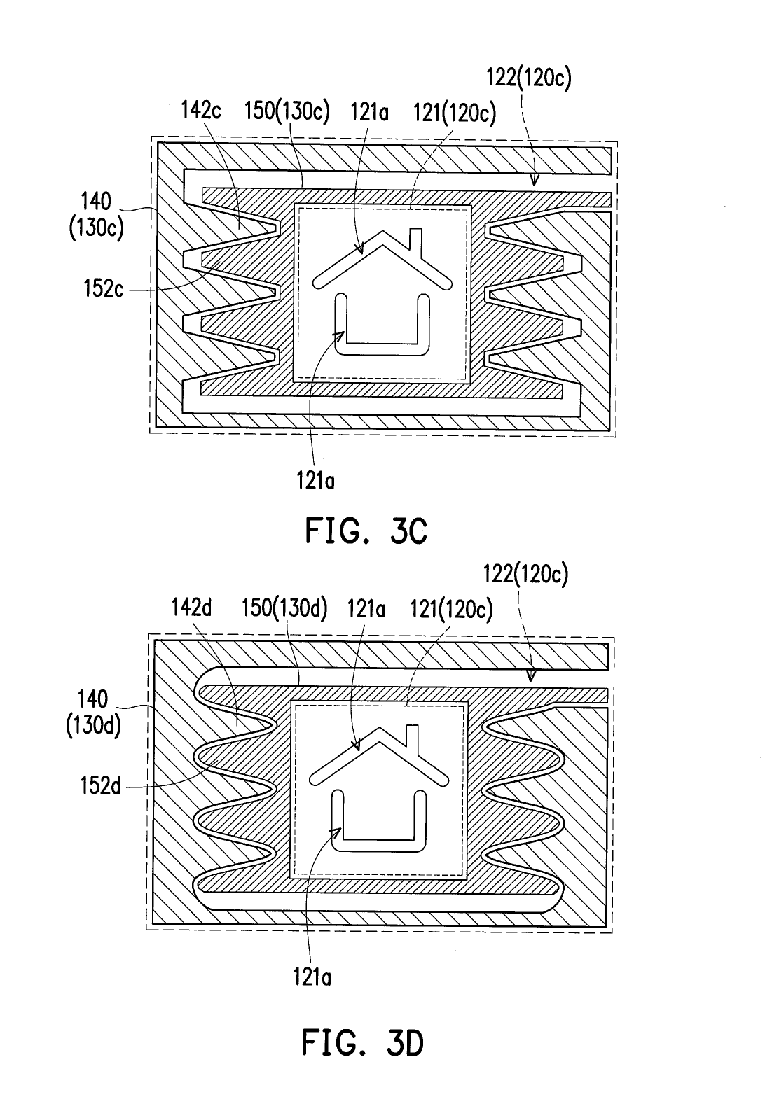

FIG. 1 is a schematic view of a touch panel according to an embodiment of the invention. FIG. 2A is a schematic view of partial layout of the conductive electrode structure located in an area A of FIG. 1. FIG. 2B is a cross-sectional schematic view along a line I-I of FIG. 2A. For the purpose of clarity, sizes, relative sizes and shapes of each element, each layer, and each area may be appropriately exaggerated in FIG. 2B. Please refer to FIG. 1, FIG. 2A, and FIG. 2B. In the present embodiment, a touch panel 100 includes a substrate 110, at least one decoration layer 120, and a conductive electrode structure 130. To be more specific, the substrate 110 is, for example, a touch module of a smart phone or a tablet computer or a cover substrate of an electronic device. The cover substrate is capable of covering and protecting the touch module or the electronic device and may be, for example, a light transmissive glass substrate or 1 acrylic substrate. In addition, the cover substrate may also have a strengthening or embellishment function achieved with the surface thereof being chemically or physically processed, but the invention is not limited thereto.

In the present embodiment, the decoration layer 120 is disposed on the substrate 110, as shown in FIG. 2B. The decoration layer 120 is, for example, a multi-layer structure formed by stacking an ink layer 120a and a photoresist layer 120b in order. For example, the decoration layer 120 may also be a single-layer structure formed by an ink layer having a high optical density (OD) or a photoresist layer with high optical density (OD), whose optical density (OD) is preferably greater than 2.5. Additionally, in other embodiments that are not shown, the decoration layer 120 may also be a multi-layer structures or a single-layer structure formed by stacking either one of the ink layers 120a of the photoresist layer 120b, but the invention is not limited thereto.

The decoration layers 120 may be disposed on at least one side of the substrate 100, but the invention is not limited thereto. For example, as shown in FIG. 1, the decoration layer 120 may be disposed on the peripheral area of the substrate 100 to define an operating area AA that is substantially a rectangular shape. An electrode structure applied to a driving/sensing function may be disposed on the operating area AA. Alternatively, the touch panel 100 may also be equipped with a sensing component used for sensing a touch operation of a user in the operating area AA. However, the invention is not intent to limit that the operating area AA has to be provided with the driving/sensing function, and in other embodiments, the operating area AA may merely be a light transmissive area without having a touching function.

Specifically, the ink layer 120a may be formed on substrate 110 through a process such as a gravure printing process, a screen printing process, a flexographic printing process, an offset printing, a reverse printing process, an ink jet printing process, and the like. On the other hand, the photoresist layer 120b may be formed on the ink layer 120a by one of the aforementioned printing processes or solely formed on the substrate 110. The photoresist layer 120b may be, for example, a black ink layer having a high optical density so as to effectively reduce light transmittance. In other words, by disposing the decoration layer 120 on the substrate 110, the user may be prevented from directly seeing through the circuit layout in the peripheral area of the touch panel 100.

Referring to FIG. 2A and FIG. 2B, at least a hot key area 120c is disposed on the decoration layer 120, and each hot key area 120c further includes a hot key pattern area 121 and a hot key touching area 122. The hot key touching area 122 is located on at least one side of the hot key pattern area 121 (in the present embodiment, an example where the hot key pattern area 121 is surrounded by hot key touching area 122 is illustrated) without overlapping each other, and the decoration layer 120 has at least one recess 121a disposed in the hot key pattern area 121.

On the other hand, the conductive electrode structure 130 is disposed on the decoration layer 120. The conductive electrode structure 130 is located in the hot key touching area 122, and an orthogonal projection of the conductive electrode structure 130 on the substrate 110 and an orthogonal projection of the recess 121a on the substrate 110 do not overlap with each other. More specifically, the orthogonal projections of the conductive electrode 130 and the recess 121a are formed on the substrate 110 along an auxiliary projection direction P, and the auxiliary projection direction P is perpendicular to the substrate 110. In other words, the conductive electrode structure 130 is located out of the recess 121a and does not extend into the recess 121a. The hot key pattern area 121 substantially surrounds the rectangular region around the recess 121a (as shown in FIG. 2A). The rectangular region here is only an example for the purpose of illustration, and in other embodiments, the contour and the area of the hot key pattern area 121 may vary with different designs.

In detail, the recess 121a may be, for example, a hot key pattern opening, and the contour of the hot key pattern opening is defined by the region in the hot key pattern area 121 with no decoration layer 120 formed on the substrate 110. Herein, a house icon used for returning to the home page is illustrated as an example of the hot key pattern opening, which construes no limitations in the invention. In other possible embodiments, the hot key pattern opening may also be any other predetermined function key such as a return arrow icon, a magnifier icon, or the like.

Please continue to refer to FIG. 2A and FIG. 2B. In the present embodiment, the conductive electrode structure 130 is formed by a one layer electrode, and the conductive electrode structure 130 includes a first electrode 140 and a second electrode 150. In other words, the first electrode 140 and the second electrode 150 are formed on the same layer to meet the trend toward lightness and slimness of the touch panel. Certainly, manufacturing the conductive electrode structure 130 using one layer electrode also facilitates in simplifying the manufacturing process, shortening the processing period, and lowering down the cost. In the present embodiment, the first electrode 140 is, for example, a driving electrode, the second electrode 150 is, for example, a sensing electrode, and the first electrode 140 and the second electrode 150 can be made of the same material or different materials, such as metal, conductive oxide (e.g., indium tin oxide), conductive polymer, or other conductive materials. On the other hand, the conductive electrode structure 130 is connected to a circuit (not shown), which may be used to provide driving signals to first electrode 140 and receive sensing signals from second electrode 150. Certainly, in other possible embodiments, the first electrode 140 may be, for example, a driving electrode, and the second electrode 150 may be, for example, a sensing electrode, such that the aforementioned circuit may be used for providing driving signals to first electrode 140 and receiving sensing signals from the second electrode 150.

Specifically, the touch panel 100 of the present embodiment may be, for example, a mutual-capacitance type touch panel, and namely, a mutual capacitance effect is formed between the first electrode 140 and the second electrode 150. When no touch event occurs, the circuit obtains a constant equivalent mutual capacitance. However, when a touch event occurs, the equivalent mutual capacitance between the first electrode 140 and the second electrode 150 is changed and is obtained by the circuit, such that through calculations, an exact location where the touch event occurs may be determined according to the calculation of the capacitance change.

In order to make the sensing of the touch event more precise, the contour of the first electrode 140 and the contour of the second electrode 150 are at least partially complementary to each other. As shown in FIG. 2A, in the present embodiment, the first electrode 140 and the second electrode 150 respectively include main electrodes 141, 151 and a plurality of sub electrodes 142, 152 which are connected to the corresponding main electrodes 141, 151 to present two mutually engaged comb-like electrodes without contacting each other, and thereby, the mutual capacitance effect between the first electrode 140 and the second electrode 150 is increased. In other words, the sub electrodes 142 of the first electrode 140 and the sub electrodes 152 of the second electrode 150 are arranged alternately, and therein, each of the sub electrodes 142 extends toward the second electrode 150 along a direction A1, and each of the sub electrodes 152 extends toward the first electrode 140 along a direction A1.

In detail, a first gap G1 exists between each two adjacent sub electrodes 142 and 152, and a second gap G2 exists between each two adjacent main electrodes 141 and 151. On the other hand, a third gap G3 exists between each adjacent sub electrode 152 and main electrode 141, and a fourth gap G4 exists between each adjacent sub electrode 142 and main electrode 151. The aforementioned gaps are preferably 20-500 microns, and more preferably 200-300 microns.

In short, with the aforementioned layout of the conductive electrode structure 130, not only the problem such as malfunction of the touching function or delay of the touching reaction due to disconnection of the touch electrode structure 130 can be resolved, but also the mutual capacitance between the first electrode 140 and the second electrode 150 can further be increased, such that the hot key pattern area 121 on the touch panel 100 can have better touch sensitivity.

In addition, please refer to FIG. 2B. Since the recess 121a is an opening formed by penetrating through the decoration layer 120, a colored-ink layer may be additionally deposited to cover the recess 121a, such that the colored-ink layer may cover or partially cover the hot key touching area 122.

FIG. 2C is a cross-sectional schematic view of a conductive electrode structure according to another embodiment of the invention. More specifically, the recess 121a is not limit to be the aforementioned aspect of the embodiment above. For example, referring to FIG. 2C, an ink layer 120a having a low optical density (i.e., an optical density less than 2.5) may be disposed in the recess 121a. In such disposition, a user may still be able to see the contour of the hot key pattern opening, such as the house icon for returning to home page shown in FIG. 2A or other predetermined functional key icons, in the periphery of the substrate 110. In the present embodiment, the ink layer 120a in the recess 121a is a one layer structure as an example for the purpose of illustration. However, as long as the user is able to see the contour of the hot key pattern opening in the periphery of the substrate 110, in other embodiments, the ink layer 120a in the recess 121a may also be a multi-layer structure, which is not limited in the invention.

FIG. 2D is a partial layout schematic diagram of the conductive electrode structure according to another embodiment of the invention. Please refer to FIG. 2D. FIG. 2D illustrates a conductive electrode structure 130′ that is different from the conductive electrode structure 130 in FIG. 2A are in the following aspects. In the present embodiment, the hot key pattern area 121 is located in a semi-enclosed region having an opening formed by the second electrode 150, and the second electrode 150 is located in a semi-enclosed region having an opening formed by the first electrode 140. More specifically, the opening of the semi-enclosed region formed by the first electrode 140 is connected through with the opening of the semi-enclosed region formed by the second electrode 150. With the layout of the conductive electrode structure 130′, the same technical effect presented in the previous embodiments can also be achieved. The location of the opening shown in FIG. 2C is only an example for illustration, and does not construe any limitation to the invention. In other embodiments, the location of the opening of the semi-enclosed region formed by the first electrode 140 and the location of the opening of the semi-enclosed region formed by the second electrode 150 may vary with different designs.

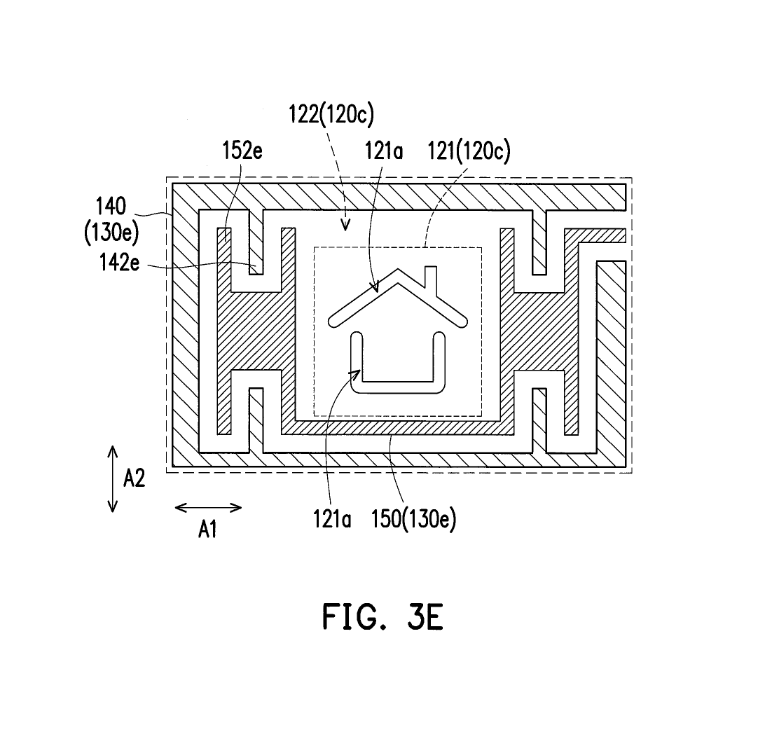

FIGS. 3A to 3E are partial layout schematic diagrams of conductive electrode structures according to other embodiments of the invention. Please refer to FIG. 3A, illustrating a conductive electrode structure 130a. In the present embodiment, the contour of first electrode 140 and the contour of second electrode 150 of the conductive electrode structure 130a are also partially complementary to each other. More specifically, the first electrode 140 has a convex part 142a extending toward the second electrode 150, and the convex part 142a is substantially a triangle shape. The second electrode 150 has a concave part 152a corresponding to the convex part 142a, such that the convex part 142a may be contained therein. The convex part 142a and the concave part 152a are engaged with each other without being contacting each other. In other words, a gap also exists between the first electrode 140 and the second electrode 150, and the gap is preferably 20-500 microns, and more preferably 200-300 microns. With the layout of the conductive electrode structure 130a, the same technical effect presented in the previous embodiments can also be achieved.

Please refer to FIG. 3B illustrating a conductive electrode structure 130b. In the present embodiment, the contour of first electrode 140 and the contour of second electrode 150 of the conductive electrode structure 130b are also partially complementary to each other. More specifically, the first electrode 140 and the second electrode 150 respectively include plate sub electrodes 142b and 152b that are corresponding to each other. The plate sub electrodes 142b are located on two sides of two plate sub electrodes 152b, while the hot key pattern area 121 and the hot key pattern opening are located between the two plate sub electrodes 152b.

More specifically, the hot key pattern area 121 and the hot key pattern opening are simultaneously surrounded by the first electrode 140 and the second electrode 150, while the first electrode 140 and the second electrode 150 are engaged with and separated from each other by a gap therebetween without contacting each other, wherein the gap is preferably 20-500 microns and more preferably 200-300 microns. With the layout of the conductive electrode structure 130b, the same technical effect presented in the previous embodiments can also be achieved.

Please refer to FIG. 3C illustrating a conductive electrode structure 130c. In the present embodiment, the contour of first electrode 140 and the contour of second electrode 150 in conductive electrode structure 130c are also partially complementary to each other. More specifically, the first electrode 140 has a dentate sub electrode 142c which extending toward the second electrode 150, and the second electrode 150 has a dentate sub electrode 152c extending toward the first electrode 140. The dentate sub electrodes 142c and 152c are arranged alternately.

More specifically, the hot key pattern area 121 and the hot key pattern opening are surrounded by the second electrode 150, and the first electrode 140 is located outside the second electrode 150. The first electrode 140 and the second electrode 150 are engaged with and separated from each other by a gap therebetween without contacting each other, wherein the gap is preferably 20-500 microns, and more preferably 200-300 microns. With the layout of the conductive electrode structure 130c, the same technical effect presented in the previous embodiments can also be achieved.

Please refer to FIG. 3D illustrating a conductive electrode structure 130d including a first electrode 140d and a second electrode 150d. The conductive electrode structure 130d of FIG. 3D and the conductive electrode structure 130c of FIG. 3C are different in the following aspects. In the present embodiment, the first electrode 140d has a wave-like sub electrode 142d extending toward the second electrode 150d, the second electrode 150d includes a wave-like sub electrode 152d extending toward the first electrode 140d, and the wave-like sub electrodes 142d and 152d are arranged alternately. With the layout of the conductive electrode structure 130d, the same technical effect presented in the previous embodiments can also be achieved.

Please refer to FIG. 3E illustrating a conductive electrode structure 130e including a first electrode 140e and a second electrode 150e. The conductive electrode structure 130e of FIG. 3E and the conductive electrode structure 130 of FIG. 2A are different in the following aspect. In the present embodiment, the sub electrodes 142e of the first electrode 140 extend toward second electrode 150 along the direction A2 and the sub electrodes 152e of second electrode 150 extend toward the first electrode 140 along the direction A2, respectively, and the direction A2 is perpendicular to the direction A1. With the layout of the conductive electrode structure 130e, the same technical effect presented in the previous embodiments can be achieved.

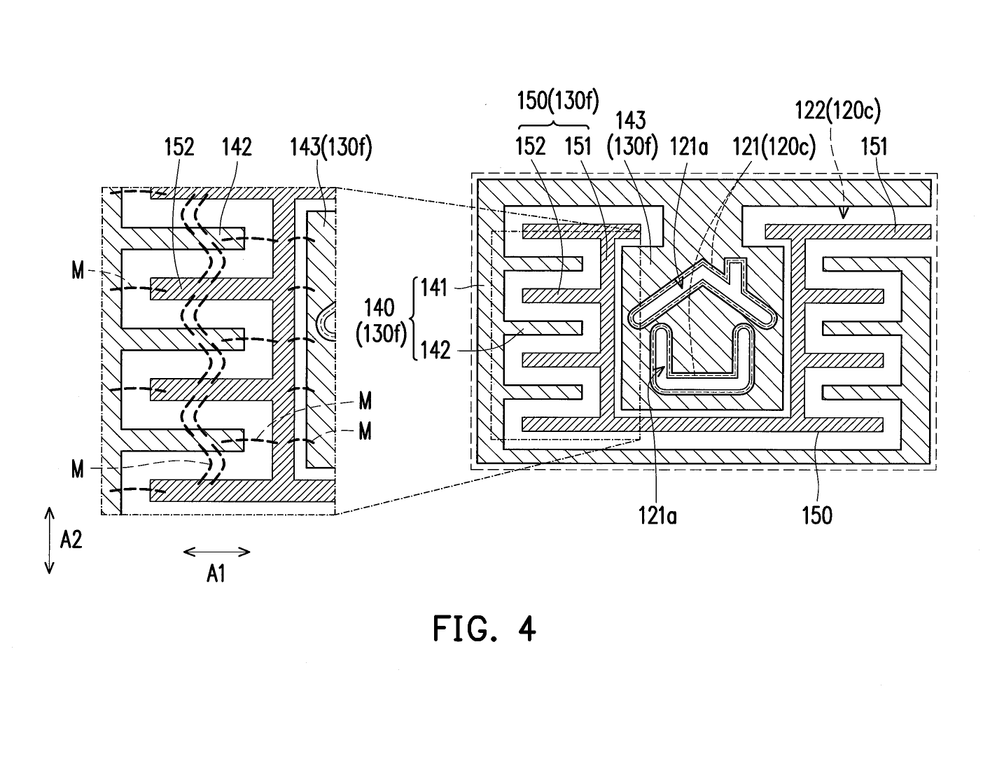

FIG. 4 is a partial layout schematic diagram of a conductive electrode structure according to another embodiment of the invention. Please refer to FIG. 2A and FIG. 4 simultaneously. FIG. 4 illustrates a conductive electrode structure 130f that is different from the conductive electrode structure 130 of FIG. 2A in the following aspects. In the present embodiment, the conductive electrode structure 130f further includes a first extending electrode 143 connected to the first electrode 140 and extending to the peripheral area of the hot key pattern area 121, and the contour of the first extending electrode 143 and the contour of the hot key pattern opening are partially complementary to each other. More specifically, the hot key pattern area 121 is, for example, a region defined along the contour of the hot key pattern opening.

That is to say, by skirting the layout of the hot key pattern opening, the first electrode 140 further extends to a semi-enclosed region having an opening that is formed by the second electrode 150 with the first extending electro 143, wherein the sub electrodes 142 and 152 in the hot key area 120c are arranged alternately, and the first extending electrode 143 is parallel to the second electrode 150 in the hot key area 120c. Therefore, along the direction A1, a plurality of parallel electric field lines M are produced between the first electrode 140 and the second electrode 150 and between the first extending electrode 143 and the second electrode 150. On the other hand, along the direction A2, a plurality of electric field lines M may also be produced between two adjacent sub electrodes 142 and 152. In such disposition, not only efficiency of the fringe capacitance in the hot key area 120c can be improved, but a sensing range of the hot key area 120c may also be increased. As a result, not only the same mutual-capacitance effect presented in the previous embodiments can be achieved, but also the sensing capability of the hot key area 120c may be significantly increased to achieve better touch sensitivity.

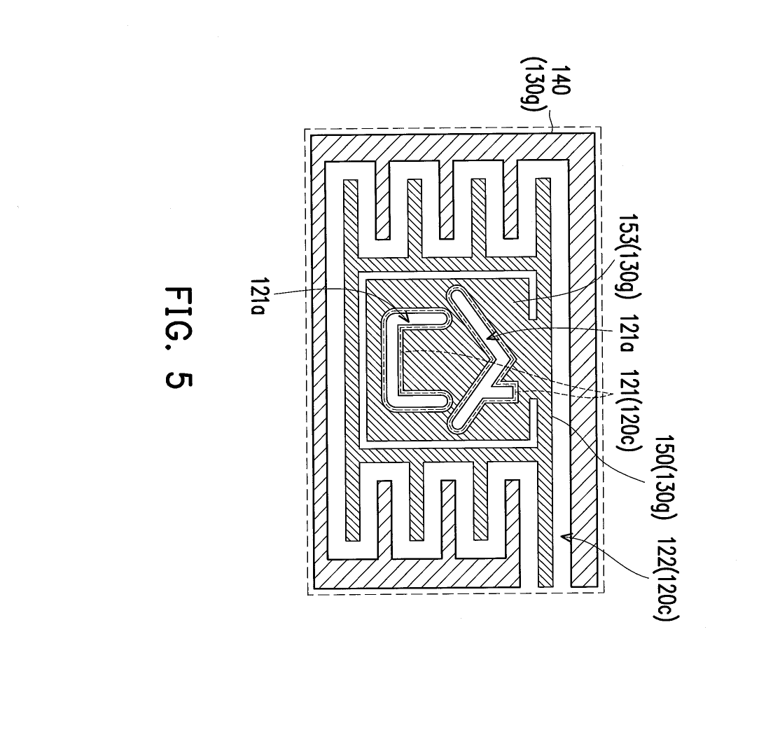

FIG. 5 is a partial layout schematic diagram of a conductive electrode structure according to yet another embodiment of the invention. Please refer to FIG. 4 and FIG. 5 simultaneously. FIG. 5 illustrates a conductive electrode structure 130g that is different from the conductive electrode structure 130f of FIG. 4 in the following aspect. In the present embodiment, the conductive electrode structure 130g further includes a second extending electrode 153 connected to the second electrode 150 and extending to the peripheral area of the hot key pattern area 121, the contour of the second extending electrode 153 and the contour of the hot key pattern opening are partially complementary to each other. The hot key pattern area 121 of the present embodiment may also be, for example, the region defined along the contour of the hot key pattern opening. In other words, with the layout skirting the hot key pattern opening, the second electrode 150 further extends to a semi-enclosed region formed by the second electrode 150 with the second extending electrode 153, and the same technical effect of the aforementioned conductive electrode structure 130f can also be achieved.

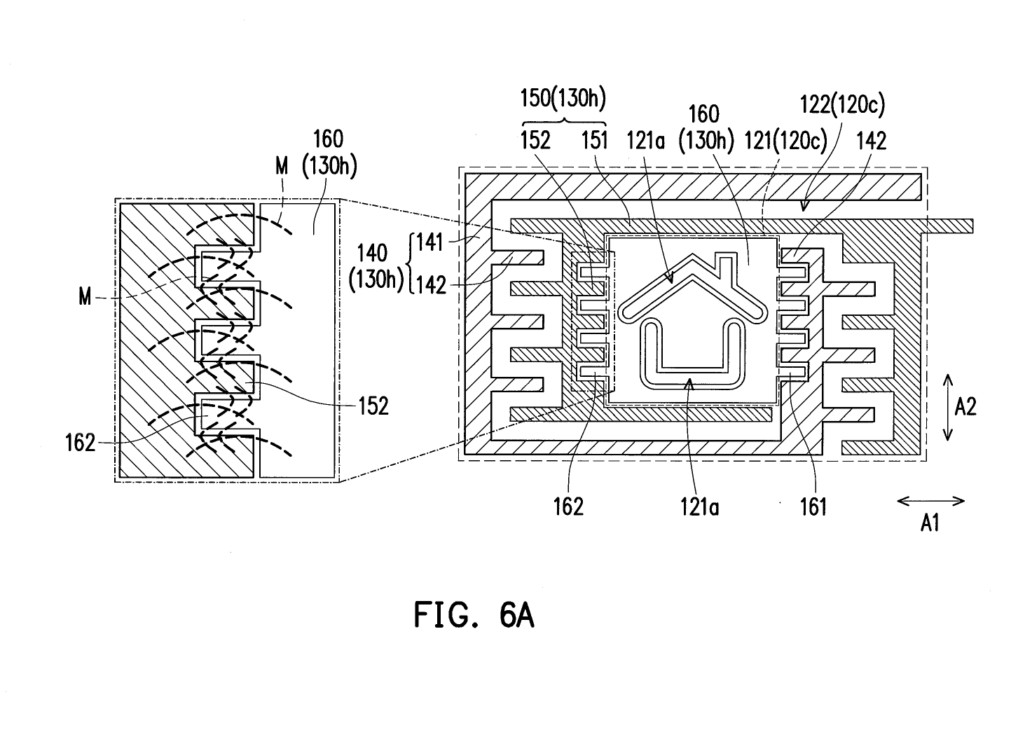

FIG. 6A and FIG. 6B are partial layout schematic diagrams of a conductive electrode structure according to still another embodiment of the invention. Please refer to FIG. 2A and FIG. 6A simultaneously. FIG. 6A illustrates a conductive electrode structure 130h that is different in the following aspect. In the present embodiment, the conductive electrode structure 130h further includes a virtual electrode 160 located between the first electrode 140 and the second electrode 150 in the hot key pattern area 120. More specifically, the virtual electrode 160 may be, for example, a floating electrode having no substantial signal connection or spatially contact with the first electrode 140 and the second electrode 150. The virtual electrode 160 may be made of, for example, indium tin oxide (ITO) or any conductive material of which the first electrode 140 and the second electrode 150 are made.

In the present embodiment, the virtual electrode 160 also utilizes a layout skirting the hot key pattern opening so as to prevent disconnection. For example, the contour of the virtual electrode 160 and the contour of the hot key pattern opening are partially complementary to each other. It is to be mentioned that since the virtual electrode 160 has no substantial signal connection with the first electrode 140 and the second electrode 150, the contour of the virtual electrode 160 and the contour of the hot key pattern opening are also unnecessarily complementary to each other. That is to say, even though the virtual electrode 160 is separated into a plurality of blocks due to the hot key pattern opening during the process of forming the virtual electrode 160 in the hot key pattern area 121, the effect of improving of the sensing capability of the conductive electrode structure 130h will not be affected.

On the other hand, the virtual electrode 160 has a plurality of virtual sub electrodes 161 and 162. The virtual sub electrodes 161 extend toward the first electrode 140 along the direction A1, the virtual sub electrodes 162 extend toward the second electrode 150 along the direction A1, and the virtual sub electrodes 161 and 162 are located outside the hot key pattern area 121. Furthermore, the part of the virtual sub electrodes 161 and the sub electrodes 142 of the first electrode 140 are arranged alternately, and the other part of the virtual sub electrodes 162 and the sub electrodes 152 of the second electrode 150 are arranged alternately. Therefore, as shown in FIG.

6A, a plurality of parallel electric field lines M with an offset relative to the direction A1 is produced between the virtual sub electrode 162 and the second electrode 150 and between the sub electrode 152 and the virtual electrode 160. On the other hand, along the direction A2, a plurality of electric field lines M are produced between the adjacent sub electrode 152 and virtual sub electrode 162. With the layout, not only the effect of the fringe capacitance between the first electrode 140 and the second electrode 150 can be improved, but also the sensing range of the periphery of the hot key pattern area 121 can be further increased.

In short, with the layout of disposing the virtual electrodes 160 between the first electrode 140 and the second electrode 150, not only the same mutual-capacitance effect presented in the previous embodiments can be achieved, but also the effect of the fringe capacitance efficiency between the first electrode 140 and the second electrode 150 in the hot key pattern area 121 can be increased, such that the sensing capacity of the hot key pattern area 121 can be improved to achieve better touch sensitivity.

On the other hand, as shown in FIG. 6B, it illustrates a conductive electrode structure 130h′ that is different from the conductive electrode structure 130h of FIG. 6A in the following aspect. The virtual electrode 160 in the conductive electrode structure 130h′ may include a plurality of block virtual sub electrodes 163 arranged in an array, wherein each of the virtual sub electrodes 163 is not connected to each other, and the virtual sub electrodes 161 and 162 are also not connected to the virtual sub electrodes 163. In such disposition, the same technical efficiency presented in the previous embodiments can also be achieved.

In the present embodiment, the virtual sub electrodes 163 are illustrated as in a rectangular shape, but construes no limitations to the invention, and in other possible embodiments, the virtual sub electrodes 163 may also be arranged in an array in any other polygonal, circular or elliptic structure that are not connected to each other, or alternatively, in any other rectangular, polygonal, circular or elliptic structure, in which at least a part of the virtual sub electrodes 163 are connected to each other, irregularly arranged and but not connected to each other, or irregularly arranged and connected to each other, which construe no limitations to the invention.

It is to be mentioned that even though the virtual electrode 160 illustrated as being located between the first electrode 140 and the second electrode 150 in the aforementioned embodiment as an example, the virtual electrode 160 is also unnecessarily located between the first electrode 140 and the second electrode 150 in other embodiments depending on different layout designs the electrode structure designs. In other words, any embodiment with the disposition of the virtual electrode 160 in the hot key pattern area 121 that can lead to significant improvement of the sensitivity capacity in the hot key pattern area 121 shall be considered as falling within the scope of the invention.

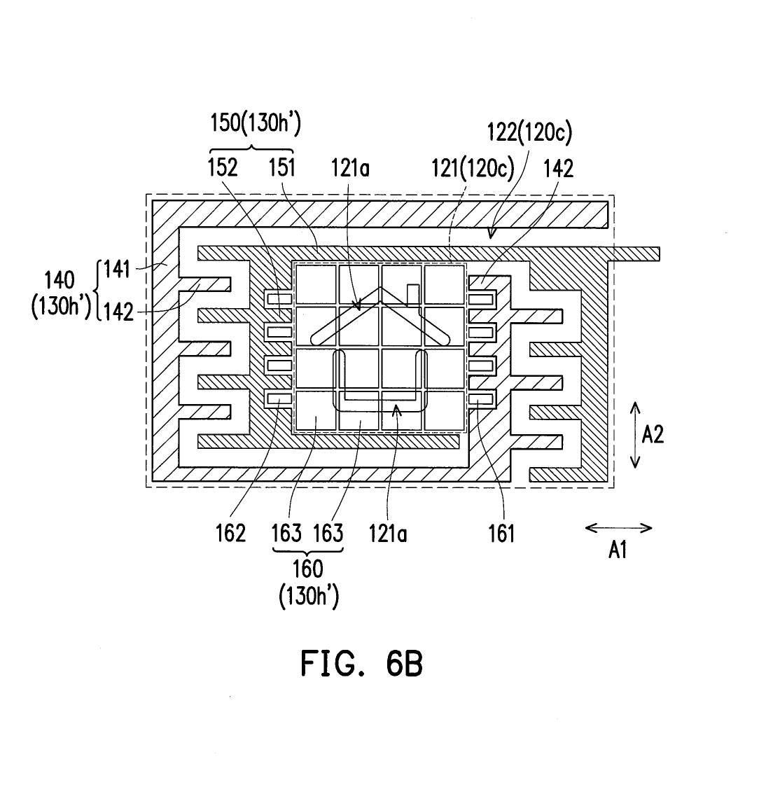

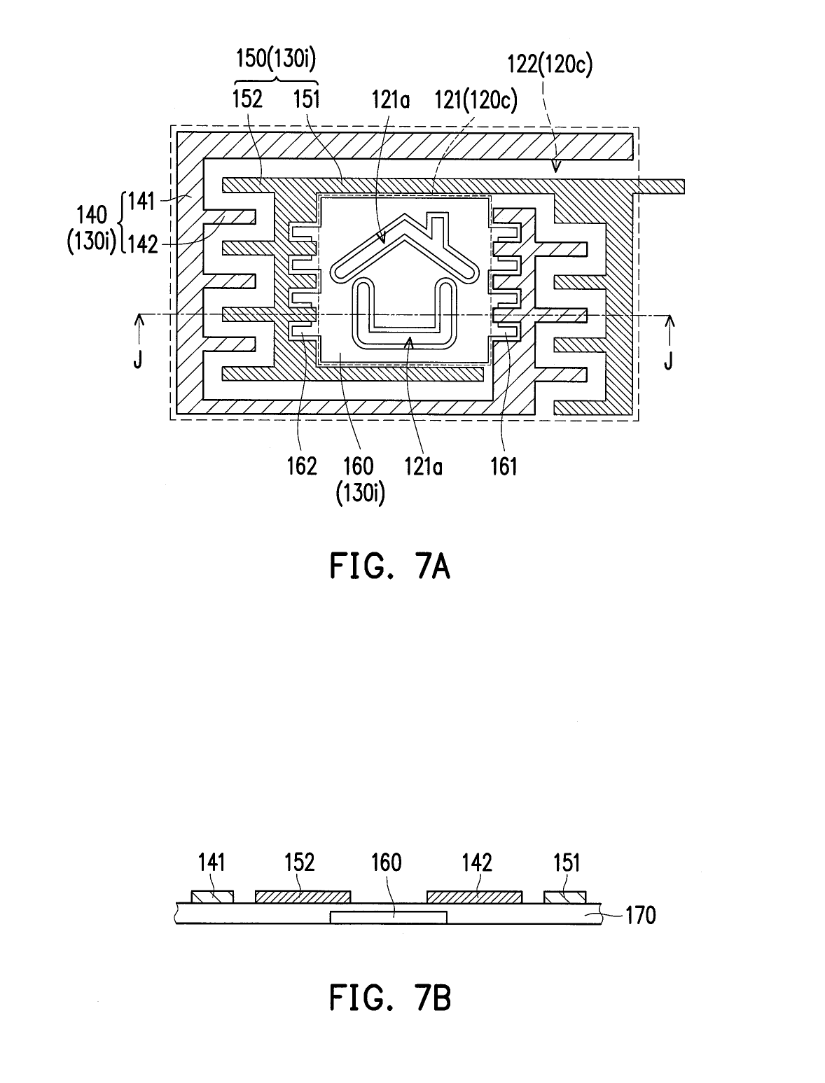

FIG. 7A is a partial layout schematic diagram of a conductive electrode structure according to further another embodiment of the invention. FIG. 7B is a schematic cross-sectional view along a line J-J of FIG. 7A. Therein, the substrate 110 and the decoration layer 120 are omitted for the purpose of clear description. Please refer to FIG. 6A and FIG. 7A simultaneously. FIG. 7A a conductive electrode structure 130i that is different from the conductive electrode structure 130h in FIG. 6A in the following aspect. In the present embodiment, a par of sub electrodes 142 and 152 of the conductive electrode structure 130i are stacked on the virtual electrode 160 to enhance conductivity of the electric field lines between the first electrode 140 and the second electrode 150 disposed in the periphery of the hot key pattern area 121.

More specifically, as shown in FIG. 7B, an insulation layer 170 is disposed between the virtual electrode 160 and the first and the second electrodes 140, 150, such that a part of the electrodes 142 and 152 stacked on the virtual electrode 160 are separated from the virtual electrode 160. Thereby, the occurrence of short circuit between the first and the second electrodes 140, 150 and the virtual electrode 160 can be prevented. On the other hand, in other possible embodiments, the layout of the virtual electrode 160 of the conductive electrode structure 130i may also be adjusted with reference to the layout design depicted in FIG. 6B, which is not limited in the invention.

In general, in other embodiments that are not shown, the layouts of the conductive electrode structures illustrated in FIG. 4A, FIG. 5, FIG. 6A, FIG. 6B, and FIG. 7A may also be adjusted with reference the layouts of the conductive electrode structures illustrated in FIG. 3A through FIG. 3E, and in the aforementioned possible layouts of the conductive electrode structure, the sensing capability of the hot key pattern area can be effectively improved to achieve better touch sensitivity.

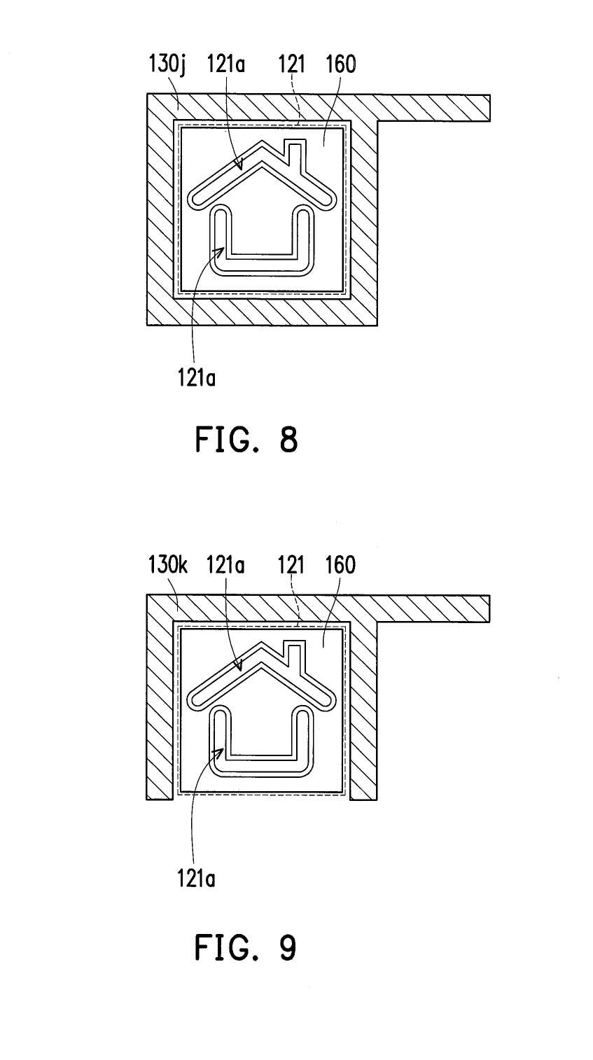

FIG. 8 and FIG. 9 are partial layout schematic diagrams of conductive electrode structures according to other possible embodiments of the invention. The invention does not limit that the conductive electrode structure has to be the layout of mutual capacitance effect, and in other possible embodiments, a conductive electrode structure 130j may be, for example, a layout of self-capacitance effect having the hot key pattern area 121 located in an enclosed region surrounded by the conductive electrode structure 130j, of which the layout is illustrated in FIG. 8. In other words, with the driving design of the self-capacitance effect, the same conductive electrode structure 130j may also perform touch operations of signal driving and sensing. The conductive electrode structure 130j is connected to an external circuit (not shown) to provide driving signals and receive sensing signals.

In addition, as shown in FIG. 9, it also illustrates a conductive electrode structure 130k of a self-capacitance effect layout. The conductive electrode structure 130k of FIG. 9 is different from the conductive electrode structure 130j of FIG. 8 in the following aspect. In the present embodiment, the hot key pattern area 121 is located in a semi-enclosed region having an opening that is surrounded by the conductive electrode structure 130k. Under such arrangement, the conductive electrode structure 130k can achieve the same technical effect as the conductive electrode structure 130j does.

It is to be mentioned that the conductive electrode structures 130j and 130k may also selectively include the virtual electrodes 160 shown in FIG. 6A and FIG. 6B or other suitable virtual electrodes in the hot key pattern area 121 to enhance the sensing capability of the conductive electrode structures 130j and 130k of the self-capacitance effect layout.

To sum up, in the touch panel of the invention, the hot key touching area is located on at least one side of the hot key pattern area without overlapping with each other, and the conductive electrode structure is disposed on the decoration layer and located in the hot key touching area. The contours of the first electrode and the second electrode of the conductive electrode structure are complementary to each other, and both are also both also complementary to the contour of the hot key pattern opening. Therefore, the layout of the conductive electrode structure skirts the hot key pattern opening so as to prevent the problem such as malfunction or the delay of the touching function due to disconnection of the conductive electrode structure passing through the hot key pattern opening.

It will be apparent to those skilled in the art that various modifications and variations can be made to the structure of the present invention without departing from the scope or spirit of the invention. In view of the foregoing, it is intended that the present invention cover modifications and variations of the invention provided they fall within the scope of the following claims and their equivalents.

What is claimed is:

1. A touch panel, comprising:
a substrate;
at least one decoration layer, disposed on at least one side of the substrate and having at least one hot key area, wherein the hot key area comprises a hot key pattern area and a hot key touching area, the hot key touching area is located on at least one side of the hot key pattern area without overlapping each other, and the decoration layer has at least one recess disposed in the hot key pattern area; and
a conductive electrode structure, disposed on the decoration layer and located in the hot key touching area, wherein an orthogonal projection of the conductive electrode structure on the substrate and an orthogonal projection of the recess on the substrate do not overlap with each other.

2. The touch panel according to claim 1, wherein the decoration layer comprises at least an ink layer, at least a photoresist layer, or a combination thereof.

3. The touch panel as claimed in claim 1, wherein the conductive electrode structure is formed by one layer electrode.

4. The touch panel as claimed in claim 1, wherein the recess is a hot key pattern opening.

5. The touch panel as claimed in claim 4, wherein the conductive electrode structure comprising a first electrodes and a second electrode, and the contour of the first electrode and the contour of the second electrode are at least partially complementary to each other.

6. The touch panel as claimed in claim 5, wherein each of the first electrode and the second electrode respectively comprises a main electrode and a plurality of sub electrodes connected to the main electrode, and the plurality of sub electrodes of the first electrode and the plurality of sub electrodes of the second electrode are arranged alternately.

7. The touch panel as claimed in claim 6, wherein each of the sub electrodes of the first electrode extends toward the second electrode, and each of the sub electrodes of the second electrode extends toward the first electrode.

8. The touch panel as claimed in claim 5, wherein the conductive electrode structure further comprises a first extending electrode connected to the first electrode and extending to the peripheral area of the hot key pattern area, and a part of the contour of the first extending electrode and the contour of the hot key pattern opening are complementary to each other.

9. The touch panel as claimed in claim 5, wherein the conductive electrode structure further comprises a second extending electrode connected to the second electrode and extending to the peripheral area of the hot key pattern area, and part of the contour of the second extending electrode and the hot key pattern opening are complementary to each other.

10. The touch panel as claimed in claim 5, wherein the conductive electrode structure comprising:
a first electrode and a second electrode, surrounding the hot key pattern area, and each comprising a main electrode and a plurality of sub electrodes connected to the main electrode; and
a virtual electrode, located between the first electrode and the second electrode and located in the hot key pattern area.

11. The touch panel as claimed in claim 10, wherein the virtual electrode has a plurality of virtual sub electrodes, wherein a part of the virtual sub electrodes extend toward the first electrode while the other part of the virtual sub electrodes extend toward the second electrode, and the plurality of virtual electrode is located outside of the hot key pattern area.

12. The touch panel as claimed in claim 11, wherein the part of the virtual sub electrodes are arranged alternately with the sub electrodes of the first electrode, while said the other part of the virtual sub electrodes are arranged alternately with the sub electrodes of the second electrode.

13. The touch panel as claimed in claim 11, wherein the contour of the part of the virtual sub electrodes and the contour of the hot key pattern opening are complementary to each other.

14. The touch panel as claimed in claim 1, wherein the conductive electrode structure is connected to an external circuit.

15. The touch panel as claimed in claim 1, wherein the recess comprises a colored ink layer therein.

16. The touch panel as claimed in claim 1, wherein the recess comprises an ink layer having a low optical density therein.

17. The touch panel as claimed in claim 16, wherein the ink layer having the low optical density has an optical density that is less than 2.5.

18. A touch panel, comprising:
a substrate;
at least one decoration layer, disposed on at least one side of the substrate and having at least one hot key area, wherein the hot key area comprises a hot key pattern area and a hot key touching area, the hot key touching area is located on at least one side of the hot key pattern area without overlapping each other, and the decoration layer has at least one recess disposed in the hot key pattern area; and
a conductive electrode structure, disposed on the decoration layer and located in the hot key touching area, wherein the conductive electrode structure is located out of the recess.

19. The touch panel as claimed in claim 18, wherein the recess is a hot key pattern opening.

20. The touch panel according to claim 18, wherein the decoration layer comprises at least an ink layer, at least a photoresist layer, or a combination thereof.
